(19) United States
(12) Patent Application Publication
(10) Pub. No.: US 2026/0344475 A1
(43) Pub. Date: Oct. 29, 2026

(54) SEMICONDUCTOR PACKAGE AND FABRICATING METHOD THEREOF

(71) Applicant: KORE SEMICONDUCTOR CO., LTD., Qingdao (CN)

(72) Inventors: Ching-Yu NI, Qingdao (CN); Wei-Ming CHEN, Qingdao (CN)

(21) Appl. No.: 19/654,008

(22) Filed: Apr. 21, 2026

(30) Foreign Application Priority Data
Apr. 23, 2025 (CN) 202510519965.X

(51) Int. Cl. H10W 70/65; H10W 70/05; H10W 74/10

(52) U.S. Cl. CPC H10W 70/65; H10W 70/05; H10W 74/111

(57) ABSTRACT

A semiconductor package and a method of fabricating the semiconductor package are provided. A first circuit portion and a second circuit portion are respectively formed on opposite sides of an interposer body to form an interposer structure. A semiconductor element is then packaged on the second circuit portion. By arranging the first circuit portion and the second circuit portion respectively on the opposite sides of the interposer body, stress within the interposer structure is balanced, thereby preventing warpage of the semiconductor package.

### BACKGROUND

### 1. Technical Field

The present disclosure relates to semiconductor packaging technology, and more particularly, to a semiconductor package having an interposer structure and a method for fabricating the same.

### 2. Description of Related Art

With the rapid development of the electronics industry, electronic products are gradually moving toward multifunctionality and high performance. Current technologies applied in the field of chip packaging include, for example, chip scale package (CSP), direct chip attached (DCA) package, or multi-chip module (MCM) package, which are flip-chip type packaging modules, as well as three-dimensional integrated circuit (3D IC) packaging technology that integrates chips via vertical stacking.

In conventional 3D IC packaging technology, a chip is disposed on an upper side of a through-silicon interposer (TSI) having a plurality of conductive through-silicon vias (TSVs), and a lower side of the through-silicon interposer is then disposed on a packaging substrate.

However, in conventional through-silicon interposers, through-silicon vias must be fabricated, which makes the manufacturing process complicated and significantly increases both material cost and processing time. As a result, it is difficult to reduce the production cost of the packaged product.

Accordingly, how to overcome the various problems of the prior art has become an urgent issue to be resolved at present.

### SUMMARY

In view of the aforementioned deficiencies of the prior art, the present disclosure provides a semiconductor package, which comprises: an interposer structure, including: an interposer body having a first side and a second side opposing the first side, wherein the interposer body includes a dielectric layer and a wiring layer bonded to the dielectric layer; a first circuit portion disposed on the first side of the interposer body, wherein the first circuit portion includes a first insulating layer and a first circuit layer bonded to the first insulating layer and electrically connected to the wiring layer; and a second circuit portion disposed on the second side of the interposer body, wherein the second circuit portion includes a second insulating layer and a second circuit layer bonded to the second insulating layer and electrically connected to the wiring layer; a semiconductor element disposed on the second circuit portion of the interposer structure and electrically connected to the second circuit layer; and a packaging layer encapsulating the semiconductor element.

The present disclosure also provides a method of fabricating a semiconductor package, and the method comprises: forming an interposer body on a carrier of full‑panel specification, the interposer body having a first side and a second side opposing the first side, and the interposer body being disposed on the carrier via the second side, wherein the interposer body includes a dielectric layer and a wiring layer bonded to the dielectric layer; forming a first circuit portion on the first side of the interposer body and electrically connecting the interposer body to the first circuit portion, wherein the first circuit portion includes a first insulating layer and a first circuit layer bonded to the first insulating layer and electrically connected to the wiring layer; removing the carrier; forming a second circuit portion on the second side of the interposer body to form a plurality of interposer structures, wherein the second circuit portion includes a second insulating layer and a second circuit layer bonded to the second insulating layer and electrically connected to the wiring layer; disposing a semiconductor element on the second circuit portion; and encapsulating the semiconductor element with a packaging layer.

The present disclosure further provides a method of fabricating a semiconductor package, and the method comprises: forming an interposer body on a carrier of full‑panel specification, the interposer body having a first side and a second side opposing the first side, and the interposer body being disposed on the carrier via the second side, wherein the interposer body includes a dielectric layer and a wiring layer bonded to the dielectric layer; forming a first circuit portion on the first side of the interposer body and electrically connecting the interposer body to the first circuit portion, wherein the first circuit portion includes a first insulating layer and a first circuit layer bonded to the first insulating layer and electrically connected to the wiring layer; removing the carrier; forming a second circuit portion on the second side of the interposer body to form a plurality of interposer structures, wherein the second circuit portion includes a second insulating layer and a second circuit layer bonded to the second insulating layer and electrically connected to the wiring layer; performing a first singulation process to separate each of the plurality of interposer structures; disposing the semiconductor element on the second circuit portion of each of the plurality of separated interposer structures; performing a re‑arrangement operation to arrange the plurality of interposer structures having the semiconductor elements on a temporary carrier; forming the packaging layer on the temporary carrier to encapsulate the plurality of interposer structures and the semiconductor elements; performing a second singulation process; and removing the temporary carrier to expose the first circuit portion.

In the aforementioned semiconductor package and method, the wiring layer has a line width/line spacing of 0.6/0.6µm.

In the aforementioned semiconductor package and method, a line width/line spacing of the first circuit layer is greater than a line width/line spacing of the wiring layer.

In the aforementioned semiconductor package and method, a line width/line spacing of the second circuit layer is greater than a line width/line spacing of the wiring layer.

In the aforementioned semiconductor package and method, the present disclosure further comprises: forming a plurality of conductive elements on the first circuit portion, the plurality of conductive elements being electrically connected to the first circuit layer.

As described above, the semiconductor package and fabricating method thereof of the present disclosure utilize the interposer body fabricated with fine line width/line spacing specifications. This not only reduces the number of layers of the first circuit layer and/or the second circuit layer, but also decreases the thickness of the semiconductor package, thereby facilitating the thinning of the semiconductor package.

Moreover, by respectively disposing the first circuit portion and the second circuit portion on the opposite first side and second side of the interposer body, the stress of the interposer structure can be balanced, thereby preventing the semiconductor package from experiencing warpage.

Furthermore, the interposer structure does not require the fabrication of TSVs, thereby reducing material costs and process time, and thus significantly lowering the manufacturing cost of the semiconductor package.

### BRIEF DESCRIPTION OF THE DRAWINGS

FIGS. 1A-1J are schematic views illustrating a method of fabricating a semiconductor package according to a first embodiment of the present disclosure.

FIG. 1K is a schematic view illustrating a subsequent application of the semiconductor package of the present disclosure.

FIGS. 2A-2I are schematic views illustrating a method of fabricating the semiconductor package according to a second embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “lower,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

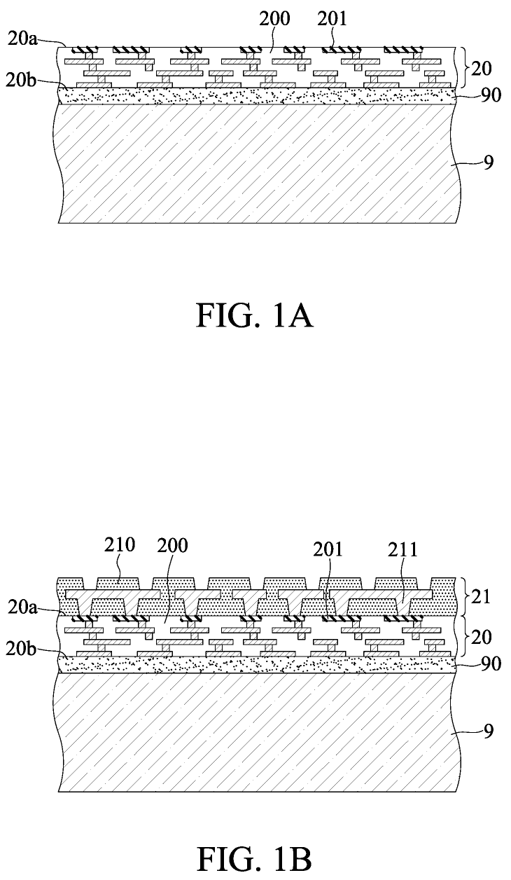

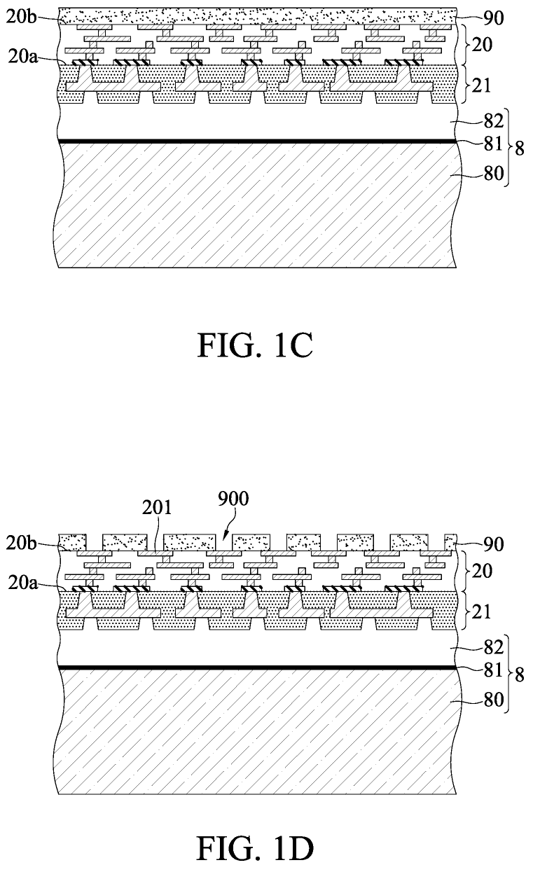

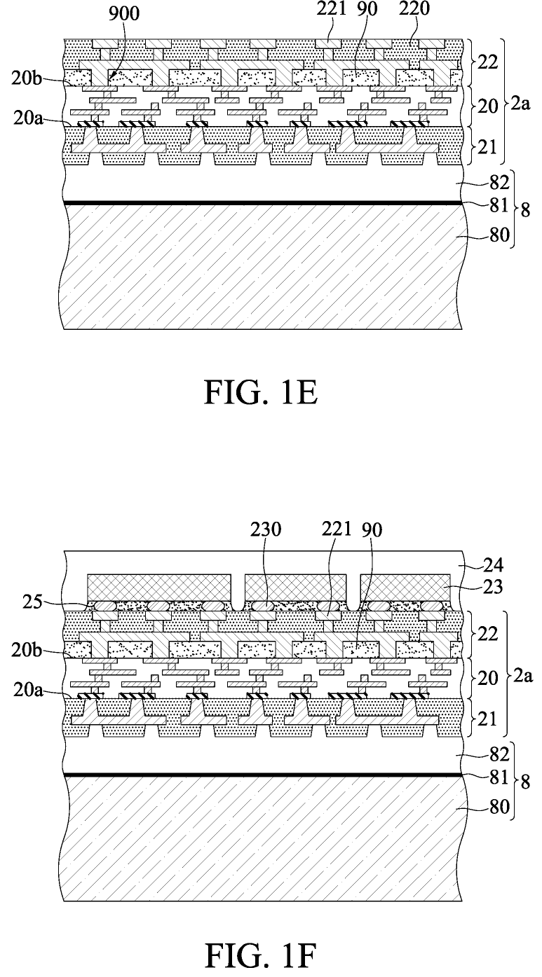

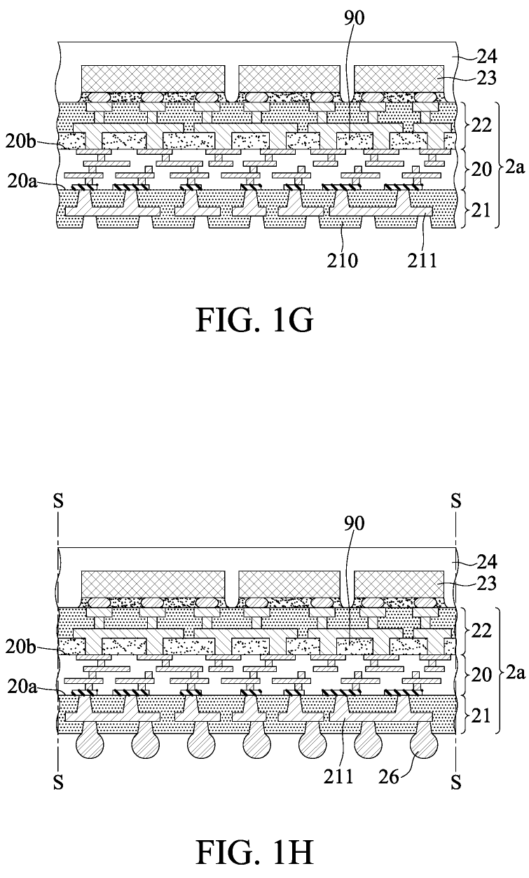

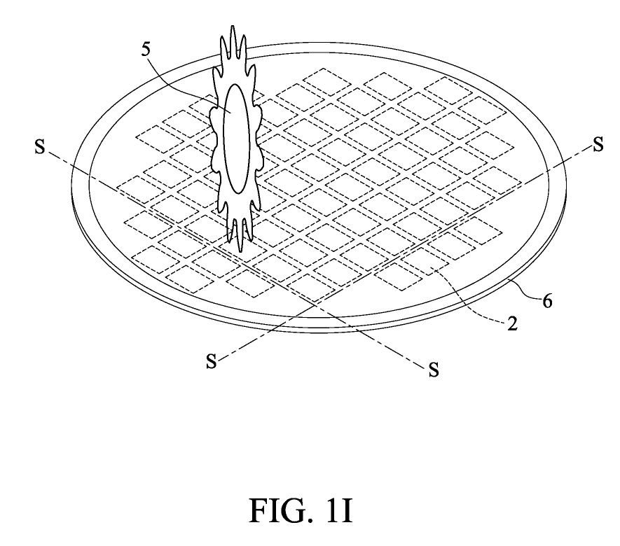

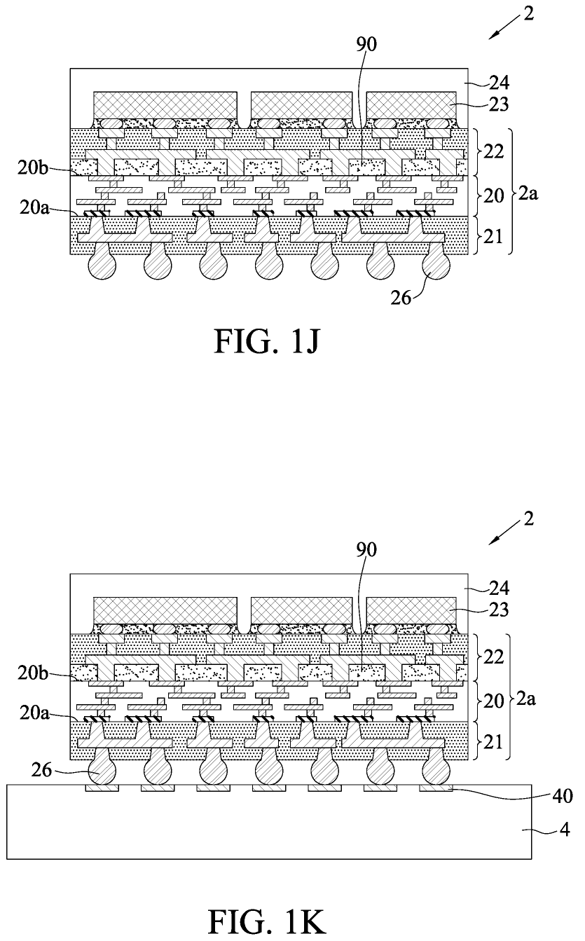

FIGS. 1A-1J are schematic views illustrating a method of fabricating a semiconductor package 2 according to a first embodiment of the present disclosure. In an embodiment, relevant processes of wafer-level packaging specifications are adopted.

As shown in FIG. 1A, a carrier 9 of full-panel specification is provided, on which a passivation layer 90 is formed. An interposer body 20 is further disposed on the passivation layer 90. The interposer body 20 has a first side 20a and a second side 20b opposing the first side 20a. The interposer body 20 is bonded to the passivation layer 90 via the second side 20b.

In an embodiment, the carrier 9 is a semiconductor board (for example, a silicon board) of full-panel specification. The passivation layer 90 is made of, for example, silicon dioxide or silicon nitride. The interposer body 20 is a back end of line (BEOL) wafer, wherein the first side 20a serves as the front side, and the second side 20b serves as the back side.

Moreover, the interposer body 20 includes at least one dielectric layer 200 and at least one wiring layer 201 bonded to the dielectric layer 200. For example, the dielectric layer 200 is made of Ajinomoto Build-up Film (ABF), polybenzoxazole (PBO), polyimide (PI), prepreg (PP), or other dielectric materials. The wiring layer 201 may be formed using patterned electroplated copper or other methods to form the required redistribution layer (RDL).

Furthermore, the dielectric layer 200 serves as an inter-metal dielectric (IMD), and the wiring layer 201 has a line width/line spacing (L/S) of 0.6/0.6 micrometers (µm).

As shown in FIG. 1B, a first circuit portion 21 is formed on the first side 20a of the interposer body 20, and the interposer body 20 is electrically connected to the first circuit portion 21.

In an embodiment, the first circuit portion 21 includes at least one first insulating layer 210 and at least one first circuit layer 211 bonded to the first insulating layer 210, wherein the wiring layer 201 is electrically connected to the first circuit layer 211. For example, the first insulating layer 210 is made of polyimide or other dielectric materials, and the first circuit layer 211 may be formed using patterned electroplated metals (such as copper, nickel, gold, tin-silver, or other metals) or other methods to form a redistribution layer.

In addition, a line width/line spacing of the first circuit layer 211 is greater than the line width/line spacing of the wiring layer 201.

As shown in FIG. 1C, a supporting structure 8 of full-panel specification is disposed on the first circuit portion 21. Then, the carrier 9 is removed, while the passivation layer 90 is retained.

In an embodiment, the supporting structure 8 includes a board body 80 made of semiconductor material (such as silicon or glass), on which a release layer 81 and a bonding layer 82 (made of such as an adhesive material) are sequentially formed, for example by coating. The bonding layer 82 is temporarily bonded to the first circuit portion 21.

Additionally, the removal of the carrier 9 is performed by first grinding to remove most of the silicon material, followed by dry etching to remove the remaining thinner silicon layer.

As shown in FIG. 1D, a plurality of openings 900 are formed in the passivation layer 90, and the wiring layer 201 is exposed through the plurality of openings 900.

In an embodiment, the openings 900 may be fabricated by patterning a photoresist to etch portions of the passivation layer 90, followed by removal of the patterned photoresist.

As shown in FIG. 1E, a second circuit portion 22 is formed on the passivation layer 90, and the interposer body 20 is electrically connected to the second circuit portion 22, thereby forming an interposer structure 2a. In the interposer structure 2a, the first circuit portion 21 and the second circuit portion 22 are respectively bonded to the first side 20a and the second side 20b of the interposer body 20, thereby presenting a sandwich structure.

In an embodiment, the second circuit portion 22 includes at least one second insulating layer 220 and at least one second circuit layer 221 bonded to the second insulating layer 220. Portions of the second circuit layer 221 extend into the openings 900 and contact the wiring layer 201, such that the wiring layer 201 is electrically connected to the second circuit layer 221. For example, the second insulating layer 220 is made of polyimide or other dielectric materials, and the second circuit layer 221 may be formed using patterned electroplated copper or other methods to form a redistribution layer.

Moreover, a line width/line spacing of the second circuit layer 221 is greater than the line width/line spacing of the wiring layer 201.

As shown in FIG. 1F, at least one semiconductor element 23 (in this embodiment, the illustration shows a plurality of semiconductor elements 23) is disposed on the second circuit portion 22, and then a packaging layer 24 is formed and encapsulates the semiconductor element(s) 23.

The semiconductor element 23 is an active element, a passive element, or a combination of the active element and the passive element. The active element is, for example, a semiconductor chip. The passive element is, for example, a resistor, a capacitor, or an inductor.

In an embodiment, the semiconductor element 23 is a semiconductor chip having an active circuit layer. The semiconductor element 23 is electrically connected to the second circuit layer 221 in a flip-chip manner via a plurality of conductive bumps 230 made of, for example, copper and/or solder material. In addition, an underfill 25 may be formed between the semiconductor element 23 and the second circuit portion 22 to encapsulate the conductive bumps 230, followed by forming the packaging layer 24 to encapsulate the underfill 25 and the semiconductor element 23. The purpose of filling the underfill 25 is to occupy a space between a lower surface of the semiconductor element 23 and an upper surface of the interposer structure 2a. Alternatively, the formation of the underfill 25 may be omitted, and the packaging layer 24 may directly encapsulate the conductive bumps 230 and the semiconductor element 23.

The packaging layer 24 is made of polyimide, dry film, molding compound/adhesive such as epoxy (epoxy resin), or other insulating materials.

In an embodiment, the packaging layer 24 is formed by a molding process, so as to protect the semiconductor element 23 and cover the upper surface of the interposer structure 2a.

As shown in FIG. 1G, the supporting structure 8 is removed, thereby exposing the first insulating layer 210 and the first circuit layer 211 of the first circuit portion 21.

In an embodiment, the removal of the supporting structure 8 may be carried out by physically peeling off the board body 80 and the release layer 81, etching away most of the material of the bonding layer 82, and laser debonding the remaining portion of the bonding layer 82. In this manner, the board body 80, the release layer 81, and the bonding layer 82 of the supporting structure 8 are removed, so that the PI material and metal material (i.e., the first insulating layer 210 and the first circuit layer 211 of the first circuit portion 21) on a lower surface of the interposer structure 2a are exposed.

As shown in FIG. 1H, a plurality of conductive elements 26, such as conductive solder balls or conductive pillars, are formed on the first circuit portion 21, and the conductive elements 26 are electrically connected to the first circuit portion 21.

In an embodiment, the conductive elements 26 are formed by a ball placing process or a surface mounting process, so as to join the conductive elements 26 to the exposed metal material (the first circuit layer 211) on the lower surface of the interposer structure 2a.

As shown in FIGS. 1I and 1J and , a singulation process is performed along cutting paths S illustrated in FIG. 1H, so as to obtain the semiconductor package 2.

In an embodiment, the interposer structure 2a, which has completed wafer-level packaging but has not yet been cut and separated, is placed with its lower surface conductive elements 26 on an adhesive layer of a carrier plate 6. A separation tool 5, such as a blade or a knife tool, is then used to perform the singulation process, and the good products are subsequently picked out.

In a subsequent process, as shown in FIG. 1K, the semiconductor package 2 may undergo a surface mount technology (SMT) process, whereby the conductive elements 26 are disposed on electrical contacts 40 of a package substrate 4. The package substrate 4 may be, for example, an ABF substrate, a bismaleimide triazine (BT) substrate, a printed circuit board (PCB) substrate, a ceramic substrate, a copper lead frame substrate, or other types of substrates.

Accordingly, in an embodiment, the method utilizes a BEOL wafer to fabricate the interposer body 20 with fine line width/line spacing specifications (L/S = 0.6/0.6µm). This not only reduces the number of layers of the first circuit layer 211 and/or the second circuit layer 221 but also decreases the thickness of the semiconductor package 2, thereby facilitating the thinning of the semiconductor package 2.

Furthermore, in an embodiment, the method arranges RDL structures (the first circuit portion 21 and the second circuit portion 22) respectively on the upper and lower sides of the interposer body 20, so as to balance the stress of the interposer structure 2a. Accordingly, the problem of warpage in the semiconductor package 2 can be avoided.

In addition, in an embodiment, the method omits the fabrication of through-silicon vias in the interposer structure 2a, thereby reducing material costs and process time, and thus significantly lowering the manufacturing cost of the semiconductor package 2.

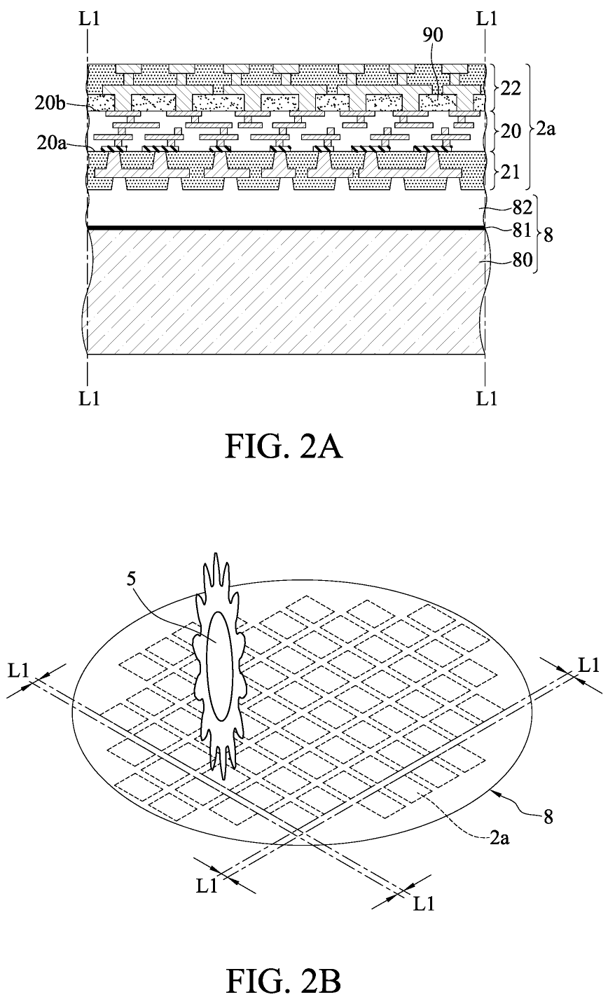

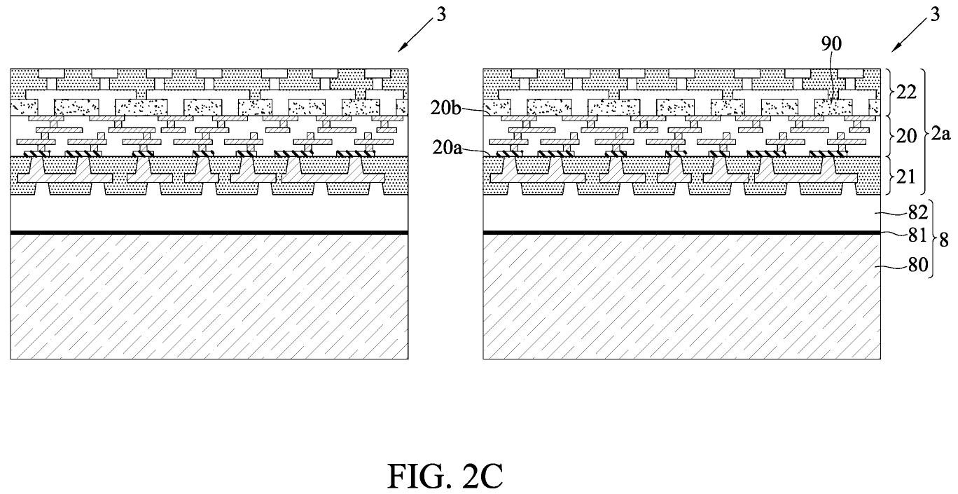

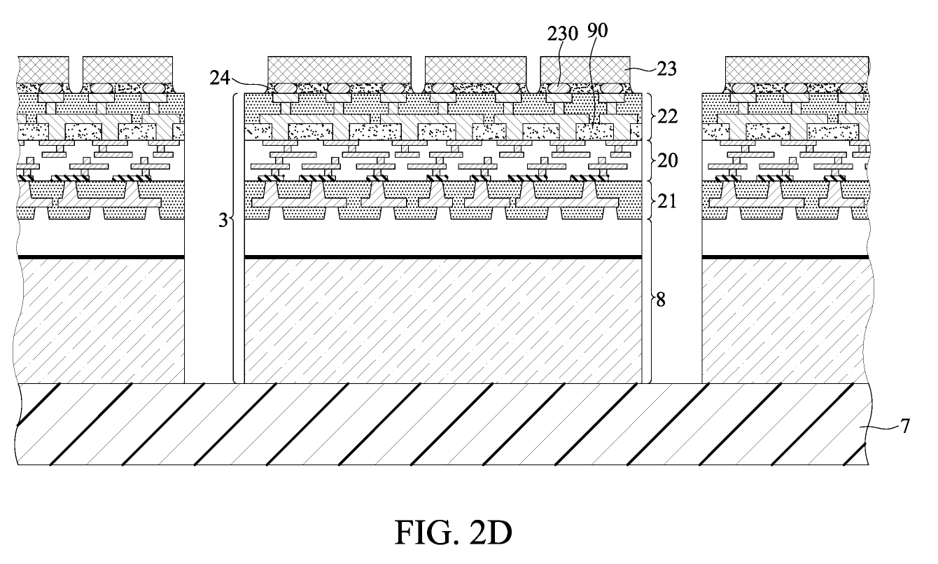

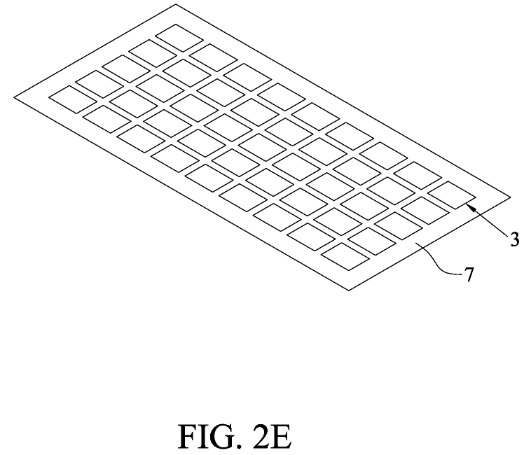

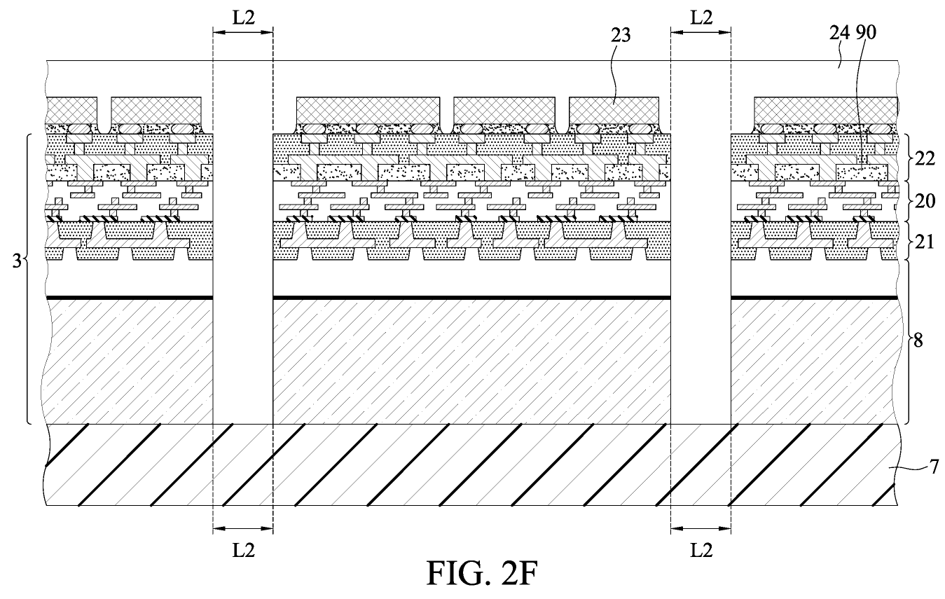

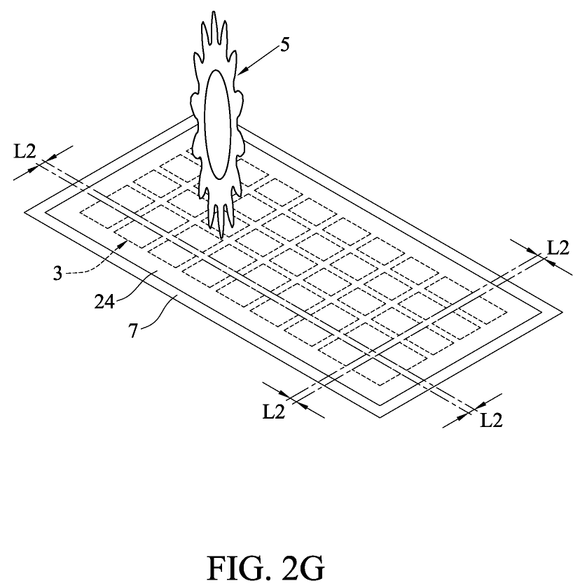

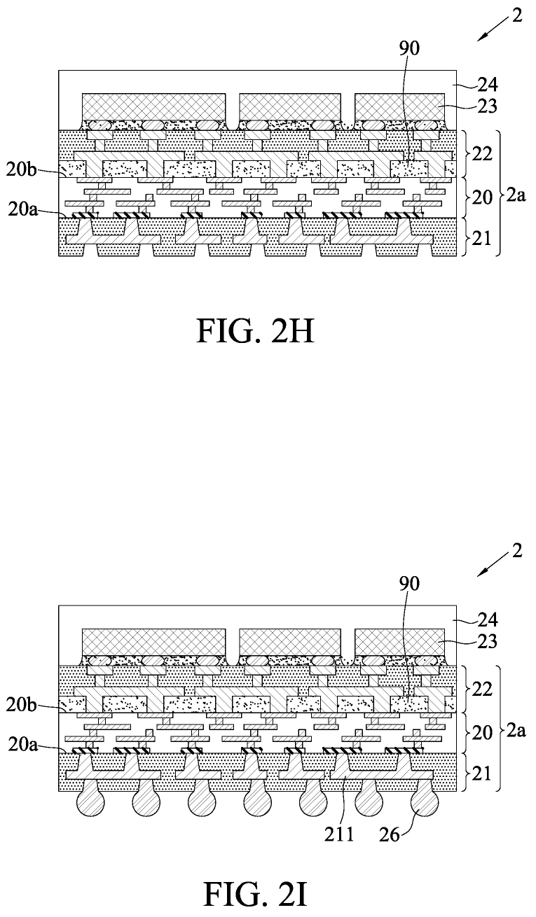

FIGS. 2A-2I to are schematic views illustrating a method of fabricating the semiconductor package 2 according to a second embodiment of the present disclosure. Since the second embodiment is generally similar to the first embodiment, the identical portions will not be redundantly described hereafter.

In an embodiment, relevant processes of single-unit-level packaging specifications are adopted.

As shown in FIG. 2A, similar to FIGS. 1A-1E illustrated previously, a sandwich-type interposer structure 2a is formed on the supporting structure 8, wherein the interposer structure 2a includes the interposer body 20 and the first circuit portion 21 and the second circuit portion 22 respectively disposed on two sides of the interposer body 20.

As shown in FIGS. 2B and 2C, a first singulation process is performed along cutting paths L1 illustrated in FIG. 2A, so as to separate each interposer structure 2a and thereby obtain a plurality of interposer blocks 3 (each of the interposer blocks 3 includes the interposer structure 2a and the supporting structure 8).

In an embodiment, the first singulation process is carried out by means of the separation tool 5, such as a blade or a knife tool.

As shown in FIGS. 2D and 2E, the semiconductor element 23 is disposed onto the second circuit portion 22 of each interposer block 3 in a flip‑chip manner (or die‑attach manner) via the plurality of conductive bumps 230, and then the conductive bumps 230 are encapsulated with the underfill 25. Then, a re‑arrangement operation is performed, in which the plurality of interposer blocks 3 having the semiconductor elements 23 are arranged with their supporting structures 8 on a temporary carrier 7.

In an embodiment, the temporary carrier 7 is in a strip‑type specification, and the interposer blocks 3 are arranged in an array manner on the temporary carrier 7.

As shown in FIG. 2F, the packaging layer 24 is formed on the temporary carrier 7 and encapsulates the interposer blocks 3 and the semiconductor elements 23 disposed on the interposer blocks 3.

In an embodiment, multiple interposer blocks 3 that have undergone flip‑chip or die‑attach processes are disposed on the temporary carrier 7, enabling the temporary carrier 7 to undergo a molding process. This achieves the purpose of protecting the semiconductor elements 23 and bonding the semiconductor elements 23 to the upper surfaces of the interposer blocks 3.

As shown in FIGS. 2G and 2H, a second singulation process is performed along cutting paths L2 illustrated in FIG. 2F. Then, the temporary carrier 7 and the supporting structure 8 are removed, thereby exposing the first circuit portion 21 and obtaining a plurality of semiconductor packages 2.

In an embodiment, the second singulation process is carried out by means of the separation tool 5, such as a blade or a knife tool, so as to cut the molded interposer blocks 3 into individual units.

Additionally, each molded interposer block 3 that has been cut into an individual unit is first removed from the temporary carrier 7. Then, by physically peeling off the board body 80 and the release layer 81, etching away most of the material of the bonding layer 82, and laser‑debonding the remaining portion of the bonding layer 82, the board body 80, the release layer 81, and the bonding layer 82 of the supporting structure 8 are removed. In this manner, the PI material and metal material (i.e., the first insulating layer 210 and the first circuit layer 211 of the first circuit portion 21) on the lower surface of the interposer structure 2a are exposed.

In a subsequent process, as shown in FIG. 2I, the plurality of conductive elements 26 are formed on the first circuit portion 21 and are electrically connected to the first circuit layer 211, so that the semiconductor package 2 may be disposed on the package substrate 4 via the conductive elements 26 (as shown in FIG. 1K).

Accordingly, in an embodiment, the method utilizes a BEOL wafer to fabricate the interposer body 20 with fine line width/line spacing specifications (L/S = 0.6/0.6µm). This not only reduces the number of layers of the first circuit layer 211 and/or the second circuit layer 221 but also decreases the thickness of the semiconductor package 2, thereby facilitating the thinning of the semiconductor package 2.

Moreover, in an embodiment, the method arranges RDL structures (the first circuit portion 21 and the second circuit portion 22) respectively on the upper and lower sides of the interposer body 20, so as to balance the stress of the interposer structure 2a. Accordingly, the problem of warpage in the semiconductor package 2 can be avoided.

Furthermore, in an embodiment, the method omits the fabrication of through-silicon vias in the interposer structure 2a, thereby reducing material costs and process time, and thus significantly lowering the manufacturing cost of the semiconductor package 2.

The present disclosure further provides a semiconductor package 2, which comprises: an interposer structure 2a, at least one semiconductor element 23, and a packaging layer 24, wherein the interposer structure 2a includes an interposer body 20, a first circuit portion 21, and a second circuit portion 22.

The interposer body 20 has a first side 20a and a second side 20b opposing the first side 20a, wherein the interposer body 20 includes at least one dielectric layer 200 and at least one wiring layer 201 bonded to the dielectric layer 200.

The first circuit portion 21 is disposed on the first side 20a of the interposer body 20, wherein the first circuit portion 21 includes at least one first insulating layer 210 and at least one first circuit layer 211 bonded to the first insulating layer 210 and electrically connected to the wiring layer 201.

The second circuit portion 22 is disposed on the second side 20b of the interposer body 20, wherein the second circuit portion 22 includes at least one second insulating layer 220 and at least one second circuit layer 221 bonded to the second insulating layer 220 and electrically connected to the wiring layer 201.

The semiconductor element 23 is disposed on the second circuit portion 22 of the interposer structure 2a and electrically connected to the second circuit layer 221.

The packaging layer 24 encapsulates the semiconductor element 23.

In an embodiment, the wiring layer 201 has a line width/line spacing of 0.6/0.6µm.

In an embodiment, a line width/line spacing of the first circuit layer 211 is greater than the line width/line spacing of the wiring layer 201.

In an embodiment, a line width/line spacing of the second circuit layer 221 is greater than the line width/line spacing of the wiring layer 201.

In an embodiment, the semiconductor package 2 further comprises: a plurality of conductive elements 26 disposed on the first circuit portion 21 and electrically connected to the first circuit layer 211.

In summary, the semiconductor package and fabricating method thereof of the present disclosure utilize the interposer body fabricated with fine line width/line spacing specifications. This not only reduces the number of layers of the first circuit layer and/or the second circuit layer, but also decreases the thickness of the semiconductor package, thereby facilitating the thinning of the semiconductor package.

In addition, by respectively disposing the first circuit portion and the second circuit portion on the upper and lower sides of the interposer body, the stress of the interposer structure can be balanced, thereby preventing the semiconductor package from experiencing warpage.

Additionally, the interposer structure does not require the fabrication of TSVs, thereby reducing material costs and process time, and thus significantly lowering the manufacturing cost of the semiconductor package.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A semiconductor package, comprising:
an interposer structure, including:
an interposer body having a first side and a second side opposing the first side, wherein the interposer body includes a dielectric layer and a wiring layer formed on the dielectric layer;
a first circuit portion disposed on the first side of the interposer body, wherein the first circuit portion includes a first insulating layer and a first circuit layer formed on the first insulating layer and electrically connected to the wiring layer; and
a second circuit portion disposed on the second side of the interposer body, wherein the second circuit portion includes a second insulating layer and a second circuit layer formed on the second insulating layer and electrically connected to the wiring layer;
a semiconductor element disposed on the second circuit portion of the interposer structure and electrically connected to the second circuit layer; and
a packaging layer encapsulating the semiconductor element.

2. The semiconductor package of claim 1, wherein the wiring layer has a line width/line spacing of 0.6/0.6µm.

3. The semiconductor package of claim 1, wherein a line width/line spacing of the first circuit layer is greater than a line width/line spacing of the wiring layer.

4. The semiconductor package of claim 1, wherein a line width/line spacing of the second circuit layer is greater than a line width/line spacing of the wiring layer.

5. The semiconductor package of claim 1, further comprising: a plurality of conductive elements disposed on the first circuit portion and electrically connected to the first circuit layer.

6. A method of fabricating a semiconductor package, comprising:
forming an interposer body on a carrier of full‑panel specification, the interposer body having a first side and a second side opposing the first side, and the interposer body being disposed on the carrier via the second side, wherein the interposer body includes a dielectric layer and a wiring layer formed on the dielectric layer;
forming a first circuit portion on the first side of the interposer body and electrically connecting the interposer body to the first circuit portion, wherein the first circuit portion includes a first insulating layer and a first circuit layer formed on the first insulating layer and electrically connected to the wiring layer;
removing the carrier;
forming a second circuit portion on the second side of the interposer body to form a plurality of interposer structures, wherein the second circuit portion includes a second insulating layer and a second circuit layer formed on the second insulating layer and electrically connected to the wiring layer;
disposing a semiconductor element on the second circuit portion; and
encapsulating the semiconductor element with a packaging layer.

7. The method of claim 6, wherein the wiring layer has a line width/line spacing of 0.6/0.6µm.

8. The method of claim 6, wherein a line width/line spacing of the first circuit layer is greater than a line width/line spacing of the wiring layer.

9. The method of claim 6, wherein a line width/line spacing of the second circuit layer is greater than a line width/line spacing of the wiring layer.

10. The method of claim 6, further comprising: forming a plurality of conductive elements on the first circuit portion, the plurality of conductive elements being electrically connected to the first circuit layer.

11. The method of claim 6, wherein the steps of disposing the semiconductor element on the second circuit portion and encapsulating the semiconductor element with the packaging layer further comprise:
performing a first singulation process to separate each of the plurality of interposer structures;
disposing the semiconductor element on the second circuit portion of each of the plurality of separated interposer structures;
performing a re‑arrangement operation to arrange the plurality of interposer structures having the semiconductor elements on a temporary carrier;
forming the packaging layer on the temporary carrier to encapsulate the plurality of interposer structures and the semiconductor elements;
performing a second singulation process; and
removing the temporary carrier to expose the first circuit portion.

12. The method of claim 11, wherein the wiring layer has a line width/line spacing of 0.6/0.6µm.

13. The method of claim 11, wherein a line width/line spacing of the first circuit layer is greater than a line width/line spacing of the wiring layer.

14. The method of claim 11, wherein a line width/line spacing of the second circuit layer is greater than a line width/line spacing of the wiring layer.

15. The method of claim 11, further comprising: forming a plurality of conductive elements on the first circuit portion, the plurality of conductive elements being electrically connected to the first circuit layer.
